(19) United States
(12) Patent Application Publication
(10) Pub. No.: US 2025/0380571 A1
(43) Pub. Date: Dec. 11, 2025

(54) LIGHT EMITTING APPARATUS, LIGHT EMITTING MODULE, IMAGE FORMING APPARATUS, AND ELECTRONIC DEVICE

(71) Applicant: CANON KABUSHIKI KAISHA, Tokyo (JP)

(72) Inventors: SHINJI NAKAMURA, Kanagawa (JP); MIZUKI NAGASAKI, Kanagawa (JP); KOICHIRO IWATA, Kanagawa (JP)

(21) Appl. No.: 19/222,584

(22) Filed: May 29, 2025

(30) Foreign Application Priority Data
Jun. 10, 2024 (JP) 2024-093959

(51) Int. Cl. H10K 59/121; H05B 45/345; H10K 59/131

(52) U.S. Cl. CPC H10K 59/1216; H05B 45/345; H10K 59/131

(57) ABSTRACT

A light emitting apparatus having first side; a second side opposed to the first side; and a third side, to which a first and a second power-supply voltages are supplied; a light emitting region including a plurality of light emitting elements in rows and a plurality of driving circuits for driving corresponding light emitting elements; a plurality of pads disposed in a region between the first side and the light emitting region, each of the pads configured to connect to a terminal arranged in an outside of the light emitting apparatus; and a capacitor element to which the first power-source voltage and the second power- source voltage are supplied, the capacitor element being disposed in a region between the second side and the light emitting region.

### BACKGROUND

### Field

The present disclosure relates to a light emitting apparatus and an image forming apparatus including the light emitting apparatus.

### Description of the Related Art

Devices using organic light emitting diodes (OLEDs) as light emitting sources have been introduced. Examples of such devices include displays (display devices) and optical writing devices (OLED print heads (OLED-PHs)) used in image forming apparatuses. The OLED-PH can have OLEDs and transistors for driving the OLEDs formed on the same substrate as each other, which is advantageous for miniaturization and cost reduction. In particular, when a silicon wafer is used as a substrate, a driving circuit can be formed with fine detail, resulting in a higher density of the OLEDs as light emitting sources. Thus, higher resolution image formation can be performed.

Japanese Patent Application Laid-Open No. 2022-162410 discusses a light emitting apparatus which reduces the impact of uneven light emission.

### SUMMARY

An aspect of the present disclosure provides a light emitting apparatus having a first side extending in a first direction, a second side opposite the first side extending in the first direction, and a third side extending in a second direction orthogonal to the first direction, to which a first power-supply voltage and a second power-supply voltage having a value different from a value of the first power-supply voltage are supplied. The light emitting apparatus includes a light emitting region including a plurality of light emitting elements disposed along the first direction; a plurality of driving circuits configured to drive corresponding light emitting elements among the plurality of light emitting elements; a plurality of pads disposed along the first direction between the first side and the light emitting region, each of the pads configured to connect to an external terminal; and a capacitor to which the first power-source voltage and the second power-source voltage are supplied, with the capacitor element is being disposed between the second side and the light emitting region.

Further features of the present disclosure will become apparent from the following description of exemplary embodiments with reference to the attached drawings.

### BRIEF DESCRIPTION OF THE DRAWINGS

FIG. 1A is a perspective diagram illustrating an example of a photosensitive drum and an OLED-PH included in an image forming apparatus. FIG. 1B is a cross-sectional diagram illustrating the photosensitive drum and the OLED-PH.

FIGS. 2A and 2B are diagrams respectively illustrating one side and the other side of a mounting surface of a printed circuit board included in the OLED-PH. FIG. 2C illustrates an enlarged view of a region V in FIG. 2B.

FIG. 3 is a cross-sectional diagram illustrating a light emitting element according to first to fourth exemplary embodiments.

FIG. 4 is a circuit block diagram of a light emitting apparatus according to the first to the fourth exemplary embodiments.

FIG. 5 is a circuit diagram of the light emitting apparatus according to the first to the fourth exemplary embodiments.

FIG. 6 is a substrate arrangement diagram of the light emitting apparatus according to the first exemplary embodiment.

FIG. 7 is a substrate arrangement diagram of the light emitting apparatus according to the second exemplary embodiment.

FIG. 8 is a substrate arrangement diagram of the light emitting apparatus according to the third exemplary embodiment.

FIG. 9 is a substrate arrangement diagram of the light emitting apparatus according to the fourth exemplary embodiment.

FIG. 10 is a schematic diagram illustrating an example of a display apparatus according to an exemplary embodiment of the present disclosure.

FIG. 11A is a schematic diagram illustrating an example of an image capturing apparatus according to an exemplary embodiment of the present disclosure. FIG. 11B is a schematic diagram illustrating an example of an electronic device according to an exemplary embodiment of the present disclosure.

FIG. 12A is a schematic diagram illustrating an example of a display apparatus according to an exemplary embodiment of the present disclosure. FIG. 12B is a schematic diagram illustrating an example of a foldable display apparatus.

FIG. 13A is a schematic diagram illustrating an example of an illumination apparatus according to an exemplary embodiment of the present disclosure. FIG. 13B is a schematic diagram illustrating an example of an automobile including a vehicle lightning fixture according to an exemplary embodiment of the present disclosure.

FIG. 14A is a schematic diagram illustrating an example of a wearable device according to an exemplary embodiment of the present disclosure. FIG. 14B is a schematic diagram illustrating an example of a wearable device according to an exemplary embodiment of the present disclosure, which includes an image capturing apparatus.

FIG. 15A is a schematic diagram illustrating an image forming apparatus according to an exemplary embodiment of the present disclosure. FIGS. 15B and 15C are schematic diagrams each illustrating a state where a plurality of light emitting units included in an exposure light source are arranged on an elongated substrate.

### DESCRIPTION OF THE EMBODIMENTS

As the progress of size reduction in light emitting apparatuses, there have been greater constraints on the arrangements and areas of bypass capacitors (capacitor elements) that are connected to a power-source voltage to reduce power-source voltage fluctuation.

To maintain the characteristics of the light emitting apparatus, it is necessary to supply a stable power-source voltage to the light emitting apparatus and circuitry mounted on the light emitting apparatus. Thus, an efficient arrangement of bypass capacitors (capacitor elements) reduces power-source voltage fluctuation.

In Japanese Patent Application Laid-Open No. 2022-162410 described above, the arrangement of bypass capacitors (capacitor elements) has not been taken into consideration. A technique according to the present disclosure relates to the arrangement of bypass capacitors (capacitor elements).

A first exemplary embodiment will now be described. An example of a light emitting apparatus according to the present exemplary embodiment will be described with reference to the drawings. Exemplary embodiments described hereinafter are examples of the present exemplary embodiment, and numerical values, shapes, materials, constituent elements, and arrangements and connection forms of the constituent elements are not intended to limit the present exemplary embodiment.

The following is a description of a light emitting apparatus 40 as an example of the light emitting apparatus. The light emitting apparatus 40 is a chip including a light emitting element and a circuit for driving the light emitting element. An exposure head that emits light onto a photosensitive drum of a copying machine will be described as an example of a light emitting module. The light emitting module can include a plurality of light emitting apparatuses 40 in a row and is not limited to the exposure head.

An organic light emitting diode (OLED) will be described as an example of the light emitting element. The present disclosure is not limited to OLEDs and can be applied to general current-driving light emitting apparatuses, such as inorganic light emitting diodes (LEDs).

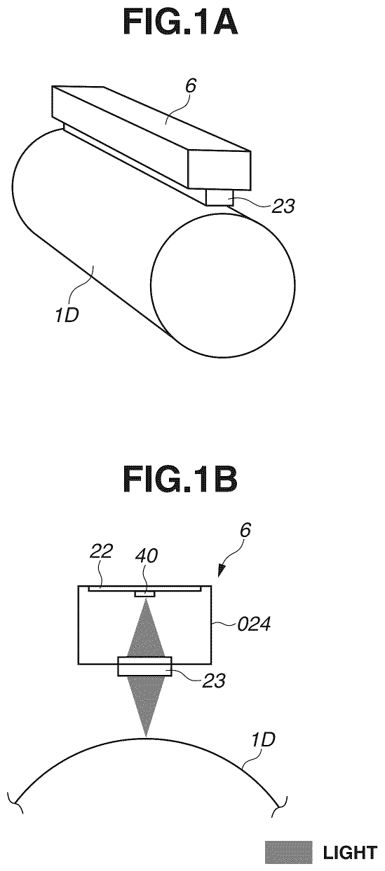

FIG. 1A is a perspective diagram illustrating an example of a photosensitive drum 1D and an organic light emitting diode print head (OLED-PH) 6 (i.e., an exposure head) included in an image forming apparatus. FIG. 1B is a cross-sectional diagram illustrating an example of the photosensitive drum 1D and the OLED-PH 6.

As illustrated in FIGS. 1A and 1B, the OLED-PH 6 is fixed at a position facing a surface of the photosensitive drum 1D by a not-illustrated fixing member. The OLED-PH 6 includes the light emitting apparatus 40 for emitting light and a printed circuit board 22 on which the light emitting apparatus 40 is mounted. The OLED-PH 6 includes a rod lens array 23 that focuses light emitted from the light emitting apparatus 40 onto the photosensitive drum 1D, and a housing 024 on which the rod lens array 23 and the printed circuit board 22 are fixed.

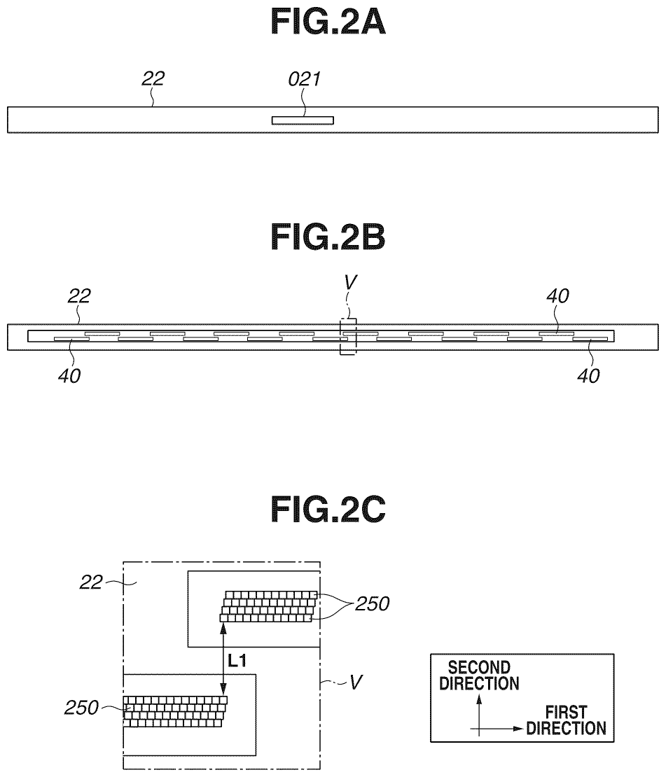

FIGS. 2A and 2B are diagrams respectively illustrating one side and the other side of a mounting surface of the printed circuit board 22 included in the OLED-PH 6. FIG. 2C illustrates an enlarged view of a region V in FIG. 2B. FIG. 2A illustrates the side of the printed circuit board 22 opposed to, i.e. opposite, the side on which the light emitting apparatuses 40 are arranged, and a connector may be disposed thereon. The connector can be connected to a control signal cable from an image controller unit and a power cable from a power source. The control signal cable can include at least one of a chip select signal line, a clock signal line, an image data signal line, a line synchronization signal line, and a communication signal line.

FIG. 2B illustrates the side of the printed circuit board 22 on which the light emitting apparatuses 40 are arranged. As illustrated in FIG. 2B, on the printed circuit board 22, 17 light emitting apparatuses 40 are arranged in two staggered rows. In each of the light emitting apparatuses 40, 872 light emitting elements 250 are arranged at predetermined resolution pitches in a longitudinal direction (a first direction).

In each of the light emitting apparatuses 40, four light emitting elements 250 are arranged at a predetermined pitch in a transverse direction (a second direction). In other words, in each of the light emitting apparatuses 40, the light emitting elements 250 are arranged two-dimensionally (in pluralities of rows and columns). The four light emitting elements 250 arranged in the transverse direction form an image through multiple exposure. The first direction and the second direction are orthogonal to each other in a plan view of the light emitting apparatus 40.

In the present exemplary embodiment the above-described resolution pitch of the light emitting apparatuses 40 can be, for example, 1200 dpi (approximately 21.16 μm). A distance (an array pitch) from one end to the other end in the longitudinal direction of the light emitting elements 250 of each light emitting apparatus 40 is, for example, approximately 18.451 mm. In this case, the array pitch of the light emitting elements 250 refers to a distance in the longitudinal direction from an end of a first electrode of a light emitting element 250 to an end of the first electrode of another light emitting element 250 adjacent to the light emitting element 250 in the longitudinal direction.

The OLED-PH 6 includes, for example, a total of 14824 light emitting elements 250 in the longitudinal direction. This enables exposure processing corresponding to an image width of approximately 315 mm (˜approximately 18.5 mm ×17 chips) in the longitudinal direction. In the transverse direction of the light emitting apparatus 40, an array pitch L1 of between the light emitting elements 250 of the light emitting apparatuses 40 adjacent to each other is approximately 350 μm. Reducing the array pitch L1 allows the light emitting elements 250 to be arranged at the center of a lens, which can improve light utilization efficiency of the light emitting apparatus 40. The array pitch L1 is set based on various types of tolerances, such as mounting tolerances of a mounting apparatus (a die bonder) and manufacturing processing tolerances of the light emitting elements.

The light emitting apparatuses 40 adjacent to each other in the second direction can be arranged so that the light emitting elements 250 in the light emitting apparatuses 40 overlap in the first direction. In the mounting process of the light emitting apparatuses 40, misalignment can occur. This causes a position of the light emitted on the photosensitive drum 1D at the boundary of each of the light emitting apparatuses 40 to shift, resulting in uneven density and formation of image streaks. However, since the light emitting elements 250 of the adjacent light emitting apparatuses 40 in the second direction are arranged to overlap with each other in the first direction, the boundary between the rows of light emitting elements 250 becomes obscure. This makes it possible to prevent uneven density and formation of image streaks caused by misalignment of the irradiation light.

An overlap amount is calculated based on the maximum tolerance in the mounting process of the mounting apparatus (the die bonder) to set such that no gap exists between the light emitting elements 250 of the light emitting apparatuses 40 adjacent to each other in the transverse direction. This makes it possible to prevent uneven density and formation of image streaks caused by positional shift of irradiation light more effectively.

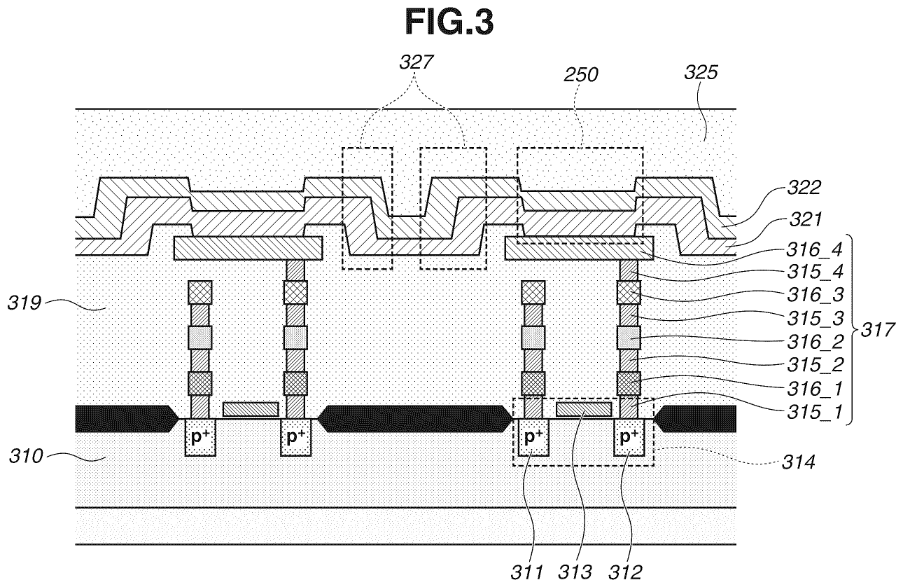

FIG. 3 is a cross-sectional diagram illustrating an example of light emitting elements and transistors connected to the respective light emitting elements. The transistor is an example of an active element. In FIG. 3, a light emitting element 250 and a transistor 314 are illustrated. A driving circuit for driving the light emitting element 250 includes the transistor 314 connected to the light emitting element 250 as illustrated in FIG. 3. The transistor 314 disposed on a silicon substrate 310 includes a gate 313 of the transistor, a drain 312 of the transistor, and a source 311 of the transistor. In this case, a metal-oxide semiconductor field-effect (MOSFET) transistor having an active layer on a single crystal silicon substrate is illustrated as an example.

The drain 312 of the transistor 314 is electrically connected to the light emitting element 250 via a wiring 317 including a plurality of contact plugs 315_1 to 315_4 and a plurality of metallic layers 316_1 to 316_4, and an insulation layer 319 is arranged between each component of the wiring 317. In FIG. 3, while the insulation layer 319 is illustrated as a single layer, the insulation layer 319 can have a multilayer consisting of a plurality of layers.

The light emitting element 250 includes the first electrode 316_4, an organic compound layer 321 having a light emitting layer, and a second electrode 322. The two first electrodes 316_4 adjacent to each other are separated by the insulation layer 319. In FIG. 3, while the organic compound layer 321 is illustrated as a single layer, the organic compound layer 321 can be a multilayer. In the light emitting element 250, the second electrode 322 is a transparent electrode, which allows light from the organic compound layer 321 to be taken to the outside. A protection layer 325 is provided above the second electrode 322 to reduce degradation of the light emitting element 250. The second electrode 322 of the light emitting element 250 is shared among a plurality of light emitting elements 250, serving as a common electrode.

Between each of the light emitting elements 250, the organic compound layer 321 is thinned with a structure 327 having a large step directly below the organic compound layer 321, and the two light emitting elements 250 are electrically separated. The second electrode 322 is electrically connected and served as a common electrode among a plurality of light emitting elements 250. In the light emitting apparatus 40, a combination of the light emitting element 250 and the driving circuit including and the transistor 314 is repeatedly arranged in a matrix direction.

A method of electrical connection between the light emitting element 250 and the electrode (the source electrode 311 or the drain electrode 312) included in the transistor 314 is not limited to that illustrated in FIG. 3. Depending on the polarity of the first electrode 316_4 and the polarity of the transistor 314, either the source electrode 311 or the drain electrode 312 of the transistor 314 can electrically be connected to the light emitting element 250.

The transistor 314 is not limited to a transistor using a single crystal silicon substrate, and can be a thin film transistor (TFT) having an active layer on an insulating surface of the substrate. Examples of the active layer include a single crystal silicon, a non-single crystal silicon, such as an amorphous silicon or a microcrystal silicon, and a non-single crystal oxide semiconductor, such as an indium zinc oxide or an indium gallium zinc oxide.

Using a transistor with a single crystal silicon wafer as the transistor 314 can miniaturize the driving circuit and increase the speed of the circuit including the transistor.

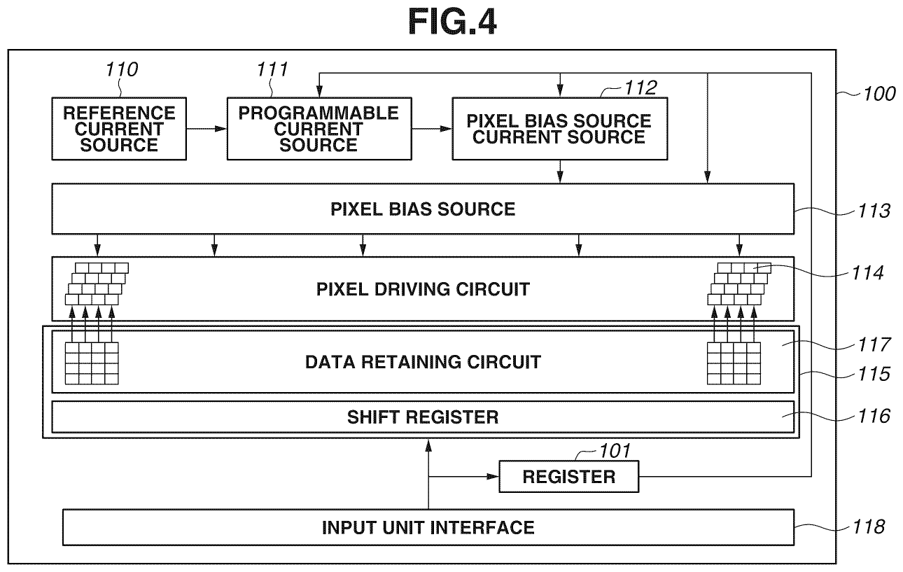

FIG. 4 is an example of a circuit block diagram of a light emitting apparatus 100 as the light emitting apparatus 40 according to the present exemplary embodiment. The light emitting apparatus 100 includes an input unit interface 118, a register 101, a reference current source 110, a programmable current source 111, a pixel bias source current source 112, a pixel bias source 113, and a pixel driving circuit 114. A horizontal scanning circuit 115 includes a data retaining circuit 117 and a shift register 116. The input unit interface 118 receives mode information for accessing a power source and a register and information about image data from an external interface, and outputs data signals to the register 101 and the horizontal scanning circuit 115.

The programmable current source 111 uses output current of the reference current source 110 as a reference to output a current to the pixel bias source current source 112 according to the digital value supplied from the register 101. The driving current of the pixel driving circuit 114 is controlled with a setting value set by the register 101. The pixel bias source current source 112 supplies an output current to the pixel bias source 113 according to the setting value set by the register 101. The pixel bias source 113 generates the bias voltage for the pixel driving circuit 114.

The pixel driving circuit 114 is connected to the light emitting elements, and a driving current is determined by a bias voltage supplied from the pixel bias source 113. The pixel driving circuit 114 performs control of emitting and not emitting light based on signals supplied from the data retaining circuit 117. The pixel driving circuit 114 includes a plurality of driving circuits, and the driving circuits each drive a corresponding light emitting element from among a plurality of light emitting elements.

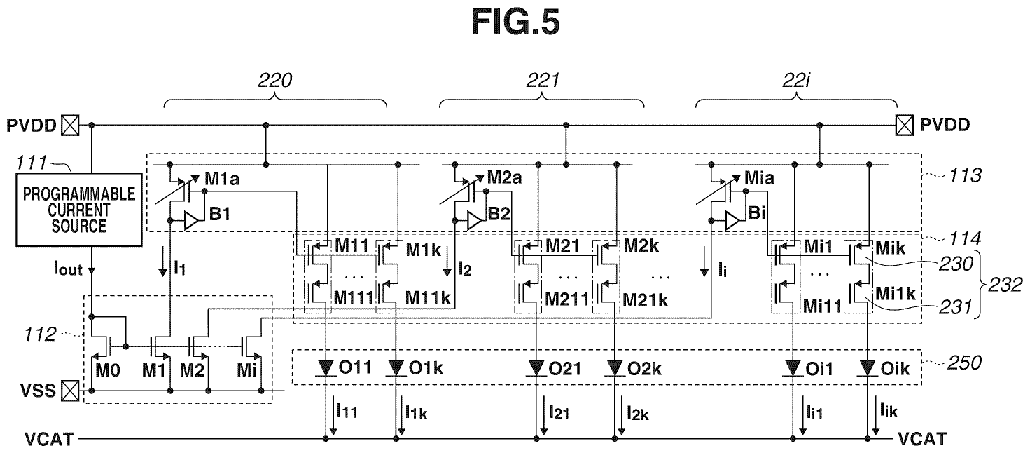

As illustrated in FIG. 5, a driving circuit 232 of the light emitting element 250 includes a first transistor 230 and a second transistor 231 connected in series. For the purpose of description, it is on the assumption that sizes of all transistors are substantially the same as each other. The pixel bias source current source 112 includes transistors M0 to Mi. The pixel bias source 113 includes transistors M1a to Mia and buffers B1 to Bi connected between the gate terminals and the drain terminals of the transistors M1a to Mia.

The pixel driving circuit 114 includes a first group of transistors M1l to Mik and a second group of transistors M11l to Mi1k. The transistors M11l to Mi1k in a second group of transistors are connected to the respective light emitting elements O1l to Oik in series. The pixel bias source 113 and the pixel driving circuit 114 are divided into a first group of circuit blocks 220 to 22i.

An output current Iₒᵤₜ of the programmable current source 111 is connected to the drain terminal of the transistor M0 of the pixel bias source current source 112. The transistor M0 is connected in diode connection, so that a voltage Vbn determined by the current Iₒᵤₜ is commonly applied to the gate terminals of the transistors M0 to Mi. Thus, the same current as the current Iₒᵤₜ flows as currents I₁ to Iᵢ.

In the first circuit block 220, the drain terminal of the transistor M1a included in the pixel bias source 113 is connected to the drain terminal of the transistor M1 in series. The gate terminal of the transistor M1a is connected to the drain terminal via a buffer B1. The buffer B1 is a voltage buffer with a gain of 1 and functions to absorb fluctuation of the gate potential of the first transistors M1l to M1k caused by light emission control operation of the driving circuit.

The transistor M1a is connected in diode connection via the buffer B1, so that a voltage V_{bp1} as a gate potential determined by the current I₁ is commonly applied to the gate terminals of the first group of transistors M1l to M1k. The voltages between the gate terminals and the source terminals of the first group of transistors M1l to M1k are equal, so that the equal driving currents I1l to I1k can be supplied to the light emitting elements O1l to O1k. The first transistors M1l to M1k function as constant current sources.

A driving voltage is applied from the data retaining circuit 117 to the gate terminals of the second transistors M11l to M11k to control whether to supply current to the light emitting elements. The second transistors M11l to M11k function as switches.

When the pixel driving circuit 114 is affected by power-source fluctuation, the current for driving the light emitting elements changes, resulting in uneven output images from the image forming apparatus. By disposing the transistor M0 and the transistors M1 to Mi close to each other to form a current mirror circuit configuration, the circuit becomes less susceptible to fluctuation in the power supply line. Thus, employing the circuit configuration according to the present exemplary embodiment is advantageous for preventing uneven output images. Similarly, disposing the transistor M1a and the first transistors M1l to M1k close to each other is advantageous for preventing uneven output images.

The light emitting elements O2l to O2k are driven by the first transistors M2l to M2k and the second transistors M21l to M21k to emit light. The light emitting elements Oil to Oik are driven by the first transistors Mil to Mik and the second transistors Mi1l to Mi1k to emit light.

In the present exemplary embodiment, the sizes of the transistors are substantially the same as each other. However, the sizes of the transistors can be adjusted with the register 101. When the sizes of the transistors M1 to Mi in the pixel bias source current source 112 are adjusted with register settings, a mirror ratio relative to the transistor M0 changes, allowing coarse adjustment of the current in the driving circuit. Similarly, when the sizes of the transistors M1a to Mia of the pixel bias source 113 are adjusted with register settings, coarse adjustment of the current in the driving circuit can be performed.

The light emitting apparatus according to the present exemplary embodiment will further be described.

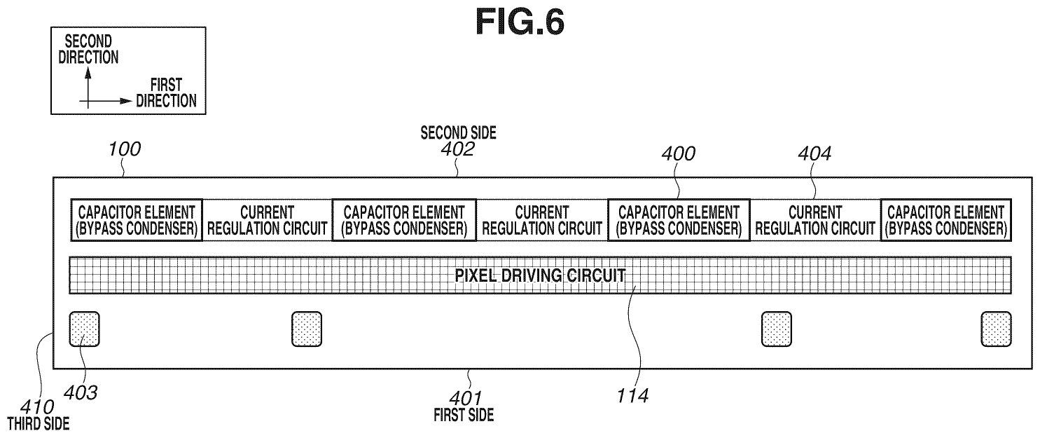

FIG. 6 is a diagram further illustrating the light emitting apparatus 100 in FIG. 4. FIG. 6 is a plan diagram illustrating an example of arrangement of a circuit block of the light emitting apparatus 100 and a placement position of capacitor elements 400. In FIG. 6, the constituent elements necessary to illustrate the placement position of the capacitor elements 400 are extracted from the circuit block illustrated in FIG. 4.

The light emitting apparatus 100 has a rectangular shape having long sides and short sides as end portions of the chip. When the direction in which the long sides extend is defined as a first direction and the direction in which the short sides extend is defined as a second direction, a first side 401 and a second side 402 extend in the first direction. A chip typically includes a silicon semiconductor substrate, and a wiring layer disposed to overlap with the semiconductor substrate.

The pixel driving circuit 114 is disposed between the first side 401 and the second side 402. The pixel driving circuit 114 drives the light emitting elements 250 arranged in the matrix as described in FIGS. 2A to 2C and FIG. 3. The periphery of the light emitting elements 250 arranged in the upper layer of the pixel driving circuit 114 is sealed with sealing material, and thus the light emitting elements 250 are disposed inward within the light emitting apparatus 100. Consequently, the pixel driving circuit 114 is also disposed inward within the light emitting apparatus 100.

A pad 403 serving as an input unit interface 118 is disposed in the first direction between the first side 401 and the pixel driving circuit 114. At least one or more pads 403 are disposed. Each of the pads 403 is connected to a terminal outside the light emitting apparatus 100. Typically, a bonding pad and a bonding wire formed of gold are connected to a pad 403. However, this is not limited to the example, and a solder ball can be connected to a pad 403. A plurality of pads 403 includes a pad used for transmitting/receiving signals to/from the outside of the light emitting apparatus 100 and a pad used for supplying the power-source voltage from the outside. Signals input to a pad 403 from the outside include a signal for controlling the current amount in a current regulation circuit 404 and a signal for controlling the operation timing of the pixel driving circuit 114.

The capacitor elements 400 are disposed between the second side 402 and the pixel driving circuit 114. The current regulation circuits 404 are disposed between the second side 402 and the pixel driving circuit 114 in the first direction.

A capacitor element 400 is electrically connected between a first power-source voltage and a second power-source voltage of a current regulation circuit 404. A capacitor element 400 includes two electrodes. One of the electrodes is connected to a node to which the first power-source voltage is supplied, whereas the other is connected to a node to which the second power-source voltage is supplied.

A current regulation circuit 404 includes a plurality of the pixel bias sources 113 illustrated in FIGS. 4 and 5, and can also include one of or both the programmable current source 111 and the pixel bias source current source 112. A current regulation circuit 404 supplies bias voltage to the pixel driving circuit 114.

The plurality of capacitor elements 400 and the plurality of current regulation circuits 404 are alternately arranged between the second side 402 and the pixel driving circuit 114 in the first direction.

At least one or more capacitor elements 400 and at least one or more current regulation circuits 404 are disposed. In the present exemplary embodiment, as in the first embodiment, a capacitor element 400 is connected between the first power-source voltage and the second power-source voltage of a current regulation circuit 404. The first power-source voltage is defined as PVDD, and the second power-source voltage as VSS.

The first power-source voltage is PVDD in FIG. 5, and the second power-source voltage is VSS in FIG. 5. PVDD can be a voltage of approximately 3V, and VSS can be a voltage of approximately zero volts. VSS can be a ground voltage.

As the power-source voltage PVDD of a current regulation circuit 404 varies, for example, a gate-source voltage (Vgs) of the transistor M1a included in the pixel bias source 113 varies. Along with this fluctuation, a bias voltage supplied to the pixel driving circuit 114 varies. Thus, a current flowing into the light emitting element 250 also varies. Consequently, an amount of light emitted from the light emitting element 250 varies, so that an uneven output image is formed in the light emitting region (i.e., the image quality is degraded).

As in the present exemplary embodiment, a capacitor element 400 is connected between PVDD and VSS to stabilize the power-source voltage of a current regulation circuit 404. This makes it possible to supply a stable power-source voltage (a bias voltage) to the pixel driving circuit 114 and prevent the above-described degradation of image quality.

Rather than disposing the capacitor elements 400 between the first side 401 and the pixel driving circuit 114, disposing the capacitor elements 400 between the second side 402 and the pixel driving circuit 114 as in the present exemplary embodiment allows a capacitor element 400 to be positioned closer to a current regulation circuit 404. Thus, it is more effective in reducing fluctuation in at least one of the first power-source voltage and the second power-source voltage.

Consequently, the capacitor elements 400 can be downsized when the capacitor elements 400 are disposed between the second side 402 and the pixel driving circuit 114 as compared with the case where the capacitor elements 400 are disposed between the first side 401 and the pixel driving circuit 114. This results in a smaller size of the light emitting apparatus 100.

This makes it possible to prevent deterioration of the characteristics of the light emitting apparatus 100 while increase in size of the light emitting apparatus 100 is prevented, and achieve reduction in both cost and performance degradation.

The first power-source voltage and the second power-source voltage are respectively described as PVDD and VSS in the present exemplary embodiment. However, power sources are not limited to the above-described power sources, and can be other power sources.

A capacitor element 400 includes a first electrode connected to a node to which the first power-source voltage is supplied and a second electrode connected to a node to which the second power-source voltage is supplied.

A capacitor element 400 can be a metal-insulator-semiconductor (MIS) capacitor. As a structure of the MIS, one of the first and the second electrodes is provided inside the silicon substrate 310 illustrated in FIG. 3. The other electrode is provided as a metallic electrode, such as the gate 313. This metallic electrode is made of, for example, polysilicon. The metallic electrode and one of the first and the second electrodes inside the silicon substrate 310 are separated by a gate oxide film. The MIS capacitor can be formed as described above.

A capacitor element 400 can be a metal-insulator-metal (MIM) capacitor. A first metallic electrode as a first electrode and a second metallic electrode as a second electrode of the MIM capacitor can be formed in the same wiring layer as each other. In this case, an insulation member is provided between the first metallic electrode and the second metallic electrode on the same wiring layer. In this manner, a capacitor element 400 can be formed. As another example of the MIM capacitor, the first electrode and the second electrode can be provided in different wiring layers. In this case, an insulation member is provided between the first metallic electrode and the second metallic electrode in the different wiring layers. In this manner, a capacitor element 400 can be formed.

The present exemplary embodiment is not limited to the arrangement of the capacitor elements 400 and the current regulation circuits 404 illustrated in FIG. 6. In other words, the arrangement is not limited to an arrangement where a plurality of capacitor elements 400 and a plurality of current regulation circuits 404 are disposed alternately. For example, the capacitor elements 400 may be arranged to extend from the region of a third side 410 to a region of the side opposed to the third side 410. In other words, a plurality of capacitor elements 400 illustrated in FIG. 6 is integrally formed as a single region of the capacitor elements 400. The current regulation circuits 404 can be arranged between the region of the capacitor elements 400 and the pixel driving circuit 114.

The current regulation circuits 404 can be arranged between the capacitor elements 400 and the pixel driving circuit 114. In this case, a capacitor element 400 can be formed in a wider region. This arrangement makes it possible to supply a stable power-source voltage.

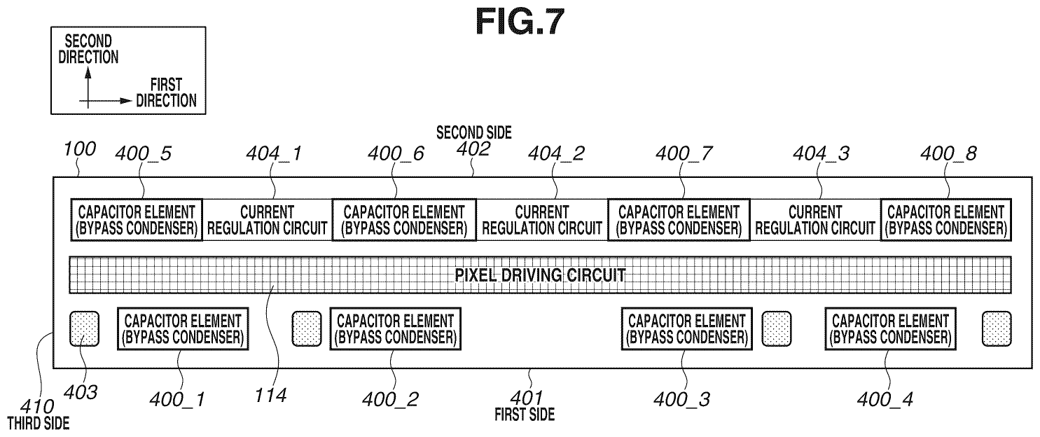

FIG. 7 is a plan diagram illustrating an example of arrangement of the circuit block constituting the light emitting apparatus 100 illustrated in FIG. 4 according to a second exemplary embodiment. The difference from the first exemplary embodiment will be described with reference to FIG. 7, with description of constituent elements illustrated in FIG. 6 being incorporated by reference, for conciseness.

Between the second side 402 and the pixel driving circuit 114, capacitor elements 400_5 to 400_8 and current regulation circuits 404_1 to 404_3 are arranged in a mixed manner in the first direction. The current regulation circuits 404_1 to 404_3 are a plurality of current regulation circuits each of which functions as a current regulation circuit.

The current regulation circuit 404_1 as a first current regulation circuit of the plurality of current regulation circuits 404_1 to 404_3 is disposed between the capacitor element 400_5 as a first capacitor element and the capacitor element 400_6 as a second capacitor element of the plurality of capacitor elements 400_5 to 400_8. The current regulation circuit 404_3 as a second current regulation circuit of the plurality of current regulation circuits 404_1 to 404_3 is disposed between the capacitor element 400_7 as a third capacitor element and the capacitor element 400_8 as a fourth capacitor element of the plurality of capacitor elements 400_5 to 400_8.

At least one or more capacitor elements 400 and at least one or more current regulation circuits 404 are disposed. As in the first exemplary embodiment, a capacitor element 400 is connected between the first power-source voltage and the second power-source voltage of the current regulation circuits 404. The first power-source voltage is defined as PVDD, and the second power-source voltage as VSS.

This configuration provides the effect of preventing image quality degradation described in the first exemplary embodiment.

In the present exemplary embodiment, the capacitor elements 400 are disposed on the side where the current regulation circuits 404 are disposed. This arrangement makes it possible to effectively reduce fluctuation of at least one of the first power-source voltage PVDD and the second power-source voltage VSS supplied to a current regulation circuit 404.

In the present exemplary embodiment, similarly to the first exemplary embodiment, deterioration of the characteristics of the light emitting apparatus 100 can be prevented without increasing the size of the light emitting apparatus 100. This makes it possible to achieve reduction in both cost and performance degradation.

The first power-source voltage and the second power-source voltage are respectively described as PVDD and VSS in the present exemplary embodiment. However, power-sources are not limited to the above-described power sources, and can be other power sources.

In the present exemplary embodiment, capacitor elements 400_1 to 400_4 are further disposed. These capacitor elements 400_1 to 400_4 are arranged between the first side 401 and the pixel driving circuit 114. The capacitor elements 400_1 to 400_4 closer to the first side 401 are arranged in a dead space where no circuit element is disposed. Each of the capacitor elements 400_1 to 400_4 is also connected to the first power-source voltage PVDD and the second power-source voltage VSS. At least one of the capacitor elements 400_1 to 400_4 is a fifth capacitor element disposed between the first side 401 and a light emitting region. Among the capacitor elements 400_1 to 400_4 between the first side 401 and the pixel driving circuit 114, the capacitor element 400_1 is disposed between the third side 410 and the capacitor element 400_2. The capacitor element 400_4 is disposed between the side (a fourth side) opposite to the third side 410 and the capacitor element 400_3. If the capacitor element 400_1 is considered to be the fifth capacitor element, at least one of the capacitor elements 400_2 to 400_4 is a sixth capacitor element positioned between the fifth capacitor element and the side (the fourth side) opposed to the third side 410. This configuration can further increase a capacitor value of the capacitor element 400 and stabilize at least one of the first power-source voltage and the second power-source voltage.

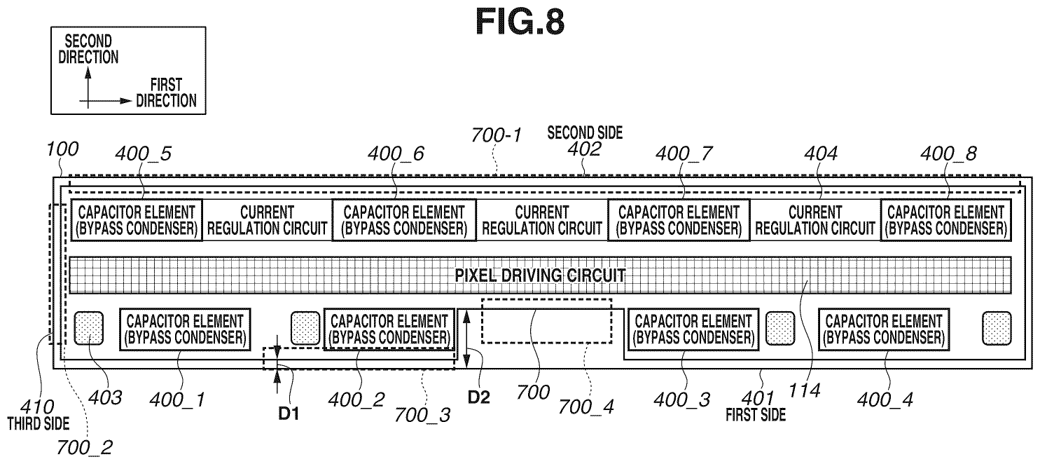

FIG. 8 is a plan diagram illustrating an example of arrangement of the circuit block constituting the light emitting apparatus 100 illustrated in FIG. 4 according to a third exemplary embodiment. The difference from the second exemplary embodiment will be described with reference to FIG. 8, with description of elements with the same reference numerals being incorporated by reference, for conciseness.

In the present exemplary embodiment, the capacitor elements 400 are arranged between the second side 402 and the pixel driving circuit 114. The capacitor elements 400 are also arranged between the first side 401 and the pixel driving circuit 114. The capacitor elements 400_1 to 400_4 closer to the first side 401 are arranged in a dead space where no circuit element is disposed.

The present exemplary embodiment will be described in detail. Metallic wiring 700 functions as a moisture-resistant ring. In the present exemplary embodiment, the metallic wiring 700 is arranged to surround the entire circumference of the light emitting apparatus 100 in a plan view relative to the light emitting region (i.e., a plan view relative to the light emitting apparatus 100). However, the present exemplary embodiment is not limited to the above-described configuration, and a part of the metallic wiring 700 can be disconnected. In a plan view seen from the direction perpendicular to the light emitting region (the light emitting apparatus 100), the metallic wiring 700 includes a first portion where the metallic wiring 700 is arranged along the first side 401, a second portion 700_1 where the metallic wiring 700 is arranged along the second side 402, and a third portion 700_2 where the metallic wiring 700 is arranged along the third side 410. The first portion includes a first region 700_3 where the metallic wiring 700 is arranged at a first distance D1 from the first side 401 in the second direction, and a second region 700_4 where the metallic wiring 700 is arranged at a second distance D2 longer than the first distance D1 from the first side 401 in the second direction. The capacitor element 400_1 as a fifth capacitor element is arranged between the second region 700_4 and the third side 410, which is between the first region 700_3 and the light emitting region. At least one of the capacitor elements 400_3 and 400_4 arranged between the side (the fourth side) opposed to the third side 410 and the second region 700_4 is a sixth capacitor element.

A capacitor element 400 is electrically connected between the first power-source voltage and the second power-source voltage, and the first power-source voltage and the second power-source voltage are supplied to a current regulation circuit 404.

The arrangement area of the capacitor elements 400 (a sum of the capacitor elements 400_5 to 400_8) arranged between the second side 402 and the pixel driving circuit 114 is greater than that of the capacitor elements 400 (a sum of the capacitor elements 400_1 to 400_4) arranged between the first side 401 and the pixel driving circuit 114.

By employing the configuration described in the present exemplary embodiment, the capacitor elements 400 connected between the first power-source voltage and the second power-source voltage can be made larger than the capacitor elements 400 described in the second exemplary embodiment, so that the power source supplied to a current regulation circuit 404 can be more stabilized.

In this manner, the capacitor elements 400 are arranged in a dead space as an effective use of the dead space. This makes it possible to prevent deterioration of the characteristics of the light emitting apparatus 100 while increase in size of the chip is prevented.

While the second region 700_4 as a recess portion along the first side 401 is illustrated as one region in FIG. 8, more recess portions can be provided.

In the configuration illustrated in FIG. 8, a capacitor element 400 is connected between the first power-source voltage and the second power-source voltage supplied to the current regulation circuits 404. Thus, the power source supplied to the current regulation circuits 404 can be more stabilized.

A fourth exemplary embodiment of the light emitting apparatus according to the present disclosure will be described specifically. The parts different from the above-described overview and the exemplary embodiments will be described. The same or similar parts are assigned the same reference numerals, and the redundant description will be omitted.

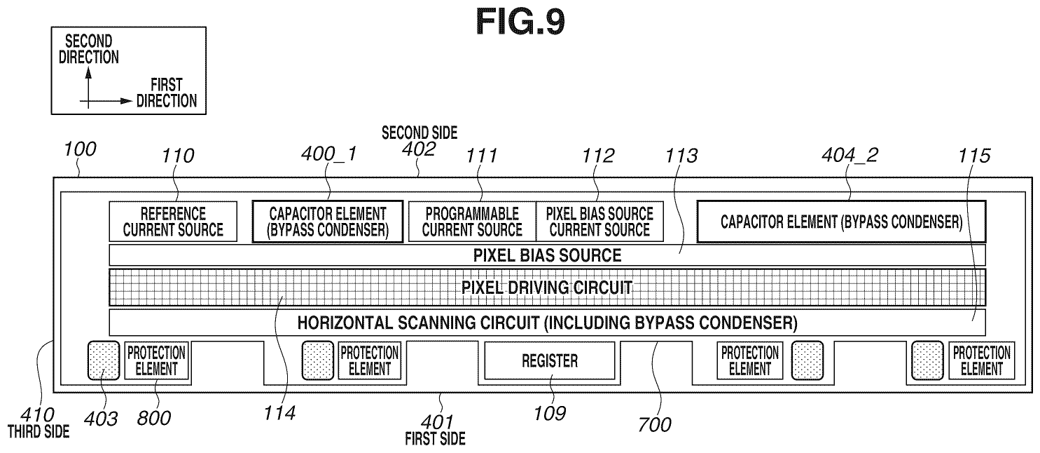

FIG. 9 is a plan diagram illustrating an example of arrangement of the circuit block of the light emitting apparatus 100 in FIG. 4.

A horizontal scanning circuit 115 is disposed in the first direction between the first side 401 and the pixel driving circuit 114.

A register 109 is disposed between the recesses portions of the metallic wiring 700 along the first side 401.

A protection element 800 for protecting an internal circuit is disposed in the vicinity of a pad 403, and external signals input to a pad 403 are supplied to the internal circuit after passing through the protection element 800.

The pixel bias source 113 is disposed between the second side 402 and the pixel driving circuit 114 in the first direction.

The reference current source 110, the programmable current source 111, and the pixel bias source current source 112 are arranged between the second side 402 and the pixel bias source 113.

The capacitor element 400_1 and the capacitor element 400_2 are disposed between or adjacent to the reference current source 110, the programmable current source 111, and the pixel bias source current source 112.

The first power-source voltage and the second power-source voltage are supplied to the reference current source 110, the programmable current source 111, and the pixel bias source current source 112, and the capacitor elements 400_1 and 400_2 are electrically connected between the first power-source voltage and the second power-source voltage. This configuration makes it possible to reduce fluctuation of the current supplied to the reference current source 110, the programmable current source 111, and the pixel bias source current source 112, preventing degradation of the image quality.

The first power-source voltage and the third power-source voltage are supplied to the pixel driving circuit 114. The first, the second, and the third power-source voltages are different from each other.

A capacitor element can be connected between the second power-source voltage and the third power-source voltage.

In the present exemplary embodiment, the first power-source voltage, the second power-source voltage, and the third power-source voltage are respectively described as PVDD, VSS, and VCAT illustrated in FIG. 5, but the power-sources are not limited thereto.

As an optical writing device used in the image forming apparatus, the light intensity of the light emitting element using an OLED is not considered sufficiently high. To increase the light intensity, applying a larger current to the light emitting element results in a higher forward voltage of the light emitting element. Thus, the light emitting element and the driving circuit connected to the light emitting element may require a potential difference greater than the first power-source voltage PVDD and the second power-source voltage VSS. In the present exemplary embodiment, the light emitting element and the driving circuit connected to the light emitting element are connected to the first power-source voltage PVDD and the third power-source voltage VCAT. Typically, a relation between PVDD, VSS, and VCAT is expressed by |PVDD−VSS|<|PVDD−VCAT|, and thus a withstand voltage of the transistor constituting the pixel driving circuit 114 is higher than that of each capacitor element 400.

In the present exemplary embodiment, in view of the withstand voltage, each capacitor element 400 cannot be arranged between the first power-source voltage and the third power-source voltage. Thus, the capacitor elements 400 are electrically connected between the first power-source voltage and the second power-source voltage and between the second power-source voltage and the third power-source voltage, respectively.

If the voltage difference between the first power-source voltage and the third power-source voltage is less than the withstand voltage of a capacitor element 400, the capacitor element 400 can be connected between the first power-source voltage and the third power-source voltage.

At least any one of the reference current source 110, the programmable current source 111, the pixel bias source current source 112, the pixel driving circuit 114, the pixel bias source 113, and a capacitor element 400 has a region partially shielded from light by a wiring arranged on the upper layer.

Herein, the upper layer refers to the area above the contact plug 315_4 illustrated in FIG. 3 (i.e., the side where the light emitting element 250 is arranged), and the wiring that shields the circuit block from light is in the same layer as that of the first electrode 316_4 in FIG. 3.

When the light emitting element 250 is formed using vapor deposition, a vapor deposition opening mask is brought into contact with at least a part of a substrate. Due to deposition blur that occurs during the vapor deposition processing, a certain distance is required between the light emitting element 250 and the second side 402. In the present exemplary embodiment, the light emitting element 250 is formed to overlap with the pixel driving circuit 114 in a plan view.

As a result, a dead space is formed between the second side 402 and the pixel driving circuit 114, and the area of the dead space ranges approximately from 0.01 mm² to 2.4 mm². The capacitor element 400 is disposed in this space.

In the present exemplary embodiment, the dead space is used to prevent increase in size of the light emitting apparatus 100 while image quality degradation due to power-source fluctuation is prevented. When a total electrode area of the light emitting elements 250 (˜the pixel driving circuit 114) arranged in the matrix direction is denoted as S, a total placement area of the capacitor elements 400 arranged between the second side 402 and the pixel driving circuit 114 as A, and an area of the light emitting apparatus 100 as 1, the areas are in a ratio of Equation (1):

$$0.006 < A < S < 1. \qquad ( 1 )$$

The configuration described in the present exemplary embodiment makes it possible to stabilize the power-source voltage and reduce the size of the light emitting apparatus whose characteristics are ensured, achieving the effect of manufacturing the light emitting apparatus at low cost.

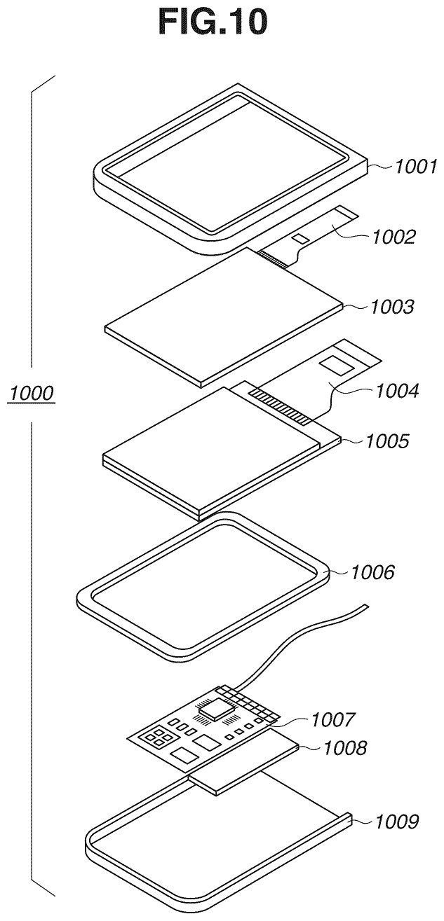

FIG. 10 is a schematic diagram illustrating an example of a display apparatus according to a fifth exemplary embodiment. A display apparatus 1000 can include a touch panel 1003, a display panel 1005, a frame 1006, a circuit substrate 1007, and a battery 1008, all of which are arranged between a top cover 1001 and a bottom cover 1009. Flexible print circuits FPC 1002 and 1004 are respectively connected to the touch panel 1003 and the display panel 1005. Transistors are disposed on the circuit substrate 1007. The battery 1008 does not need to be provided in the display apparatus 1000 if the display apparatus 1000 is not a mobile device. Even if the display apparatus 1000 is a mobile device, the battery 1008 can be disposed in a different position.

The display apparatus 1000 according to the present exemplary embodiment can include color filters of red, green, and blue. The color filters of red, green and blue can be arranged in a delta array.

The display apparatus 1000 according to the present exemplary embodiment can be used for a display unit mounted on a mobile terminal. In this case, the display apparatus 1000 can have both a display function and an operation function. Examples of the mobile terminals include a mobile phone, such as a smartphone, a tablet terminal, and a head-mounted display.

The display apparatus 1000 according to the present exemplary embodiment can be used in the display unit of an image capturing apparatus including an optical unit having a plurality of lenses and an image element for receiving light passing through the optical unit. The image capturing apparatus can include a display unit for displaying information acquired by the image sensor. Further, the display unit can be exposed to the outside of the image capturing apparatus, or can be arranged within a finder. The image capturing apparatus can be a digital camera or a digital video camera.

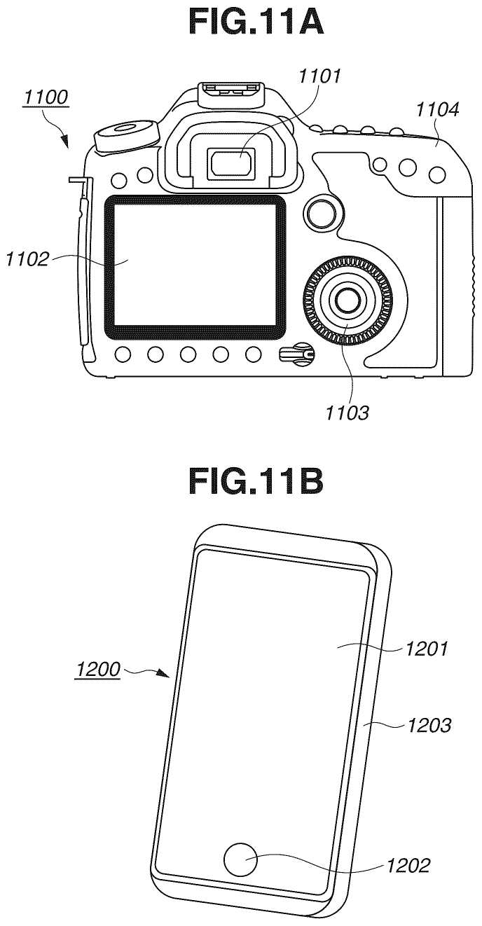

FIG. 11A is a schematic diagram illustrating an example of an image capturing apparatus according to the present exemplary embodiment. An image capturing apparatus 1100 can include a viewfinder 1101, a rear display 1102, an operation unit 1103, and a housing 1104. The viewfinder 1101 can include a display apparatus according to the present exemplary embodiment. In this case, the display apparatus may display environmental information, image capturing instructions, and other information, as well as an image to be captured. The environmental information may include an intensity of external light, a direction of external light, a speed at which an object travels, and a possibility of the object to be obscured by obstacles.

Timing suitable for capturing images is brief. Thus, displaying the information may be quickly performed. Consequently, the display apparatus using the organic light emitting element according to the present disclosure may be used because the response speed of an organic light emitting element is high. A display apparatus using the organic light emitting element can be more suitably used than a liquid crystal display apparatus that requires display speed.

The image capturing apparatus 1100 may include an optical unit. The optical unit includes a plurality of lenses, and forms an image on an image sensor accommodated in the housing 1104. The focus can be adjusted by changing the relative positions of the plurality of lenses. This operation can be performed automatically. The image capturing apparatus 1100 may also be referred to as a photoelectric conversion apparatus. The photoelectric conversion apparatus can include methods, such as detecting differences from previous images instead of sequential imaging or extracting images from continuously recorded images.

FIG. 11B is a schematic diagram illustrating an example of an electric device according to the present exemplary embodiment. An electronic device 1200 can include a display unit 1201, an operation unit 1202, and a housing 1203. The housing 1203 can include circuitry, a printed circuit board having the circuitry, a battery, and a communication unit. The operation unit 1202 can be a button or a touch panel reaction unit. The operation unit 1202 can be a biometric recognition unit that recognizes a fingerprint to unlock the device and perform another function. The electronic device including a communication unit can also be referred to as a communication device. The electronic device can include a lens and an imaging element to further have a camera function. An image captured using the camera function is displayed on the display unit. Examples of the electronic device include a smartphone and a laptop computer.

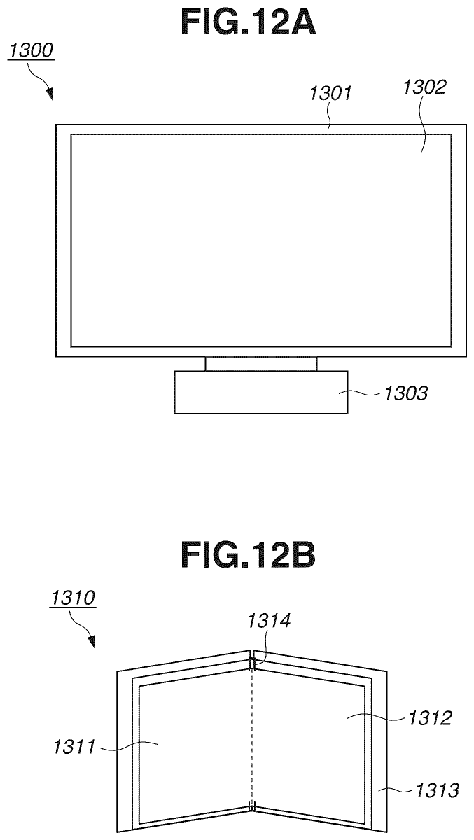

FIGS. 12A and 12B are schematic diagrams illustrating examples of the display apparatus according to the present exemplary embodiment. FIG. 12A illustrates a display apparatus, such as a television (TV) monitor or a personal computer (PC) monitor. A display apparatus 1300 includes a frame 1301 and a display unit 1302. The light emitting apparatus according to the present exemplary embodiment can be used in the display unit 1302.

The display apparatus 1300 includes a base 1303 for supporting the frame 1301 and the display unit 1302. The base 1303 is not limited to the form illustrated in FIG. 12A. A lower side of the frame 1301 may also serve as a base.

The frame 1301 and the display unit 1302 may each have a curved shape. A curvature radius of the curved shape may be in the range between 5000 mm and 6000 mm, inclusively.

FIG. 12B is a schematic diagram illustrating another example of the display apparatus according to the present exemplary embodiment. A display apparatus 1310 in FIG. 12B is a so-called foldable display apparatus capable of being folded. The display apparatus 1310 includes a first display unit 1311, a second display unit 1312, a housing 1313, and a folding point 1314. The first display unit 1311 and the second display unit 1312 can each include the light emitting apparatus according to the present exemplary embodiment. The first display unit 1311 and the second display unit 1312 can be a single seamless display apparatus. The first display unit 1311 and the second display unit 1312 can be divided at the folding point 1314. The first display unit 1311 and the second display unit 1312 can each display a different image or can display a single image together.

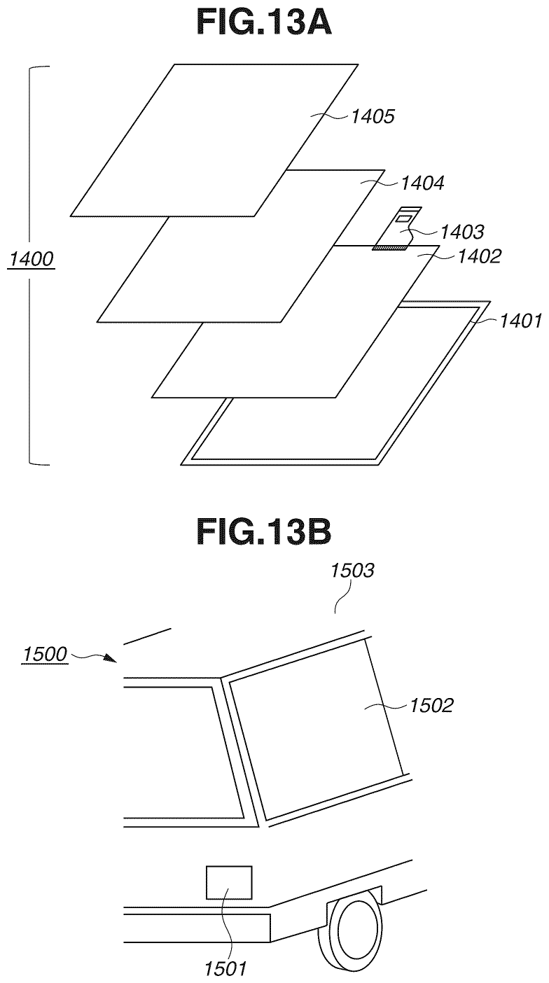

FIG. 13A is a schematic diagram illustrating an example of an illumination apparatus according to the present exemplary embodiment. An illumination apparatus 1400 can include a housing 1401, a light source 1402, a circuit substrate 1403, an optical filter 1404, and a light diffusion unit 1405. The light source 1402 can include the organic light emitting elements according to the present exemplary embodiment. The optical filter 1404 can be a filter capable of improving a color rendering property of the light source 1402. The light diffusion unit 1405 can effectively diffuse light from the light source 1402, such as for lightning up, to deliver the light over a wider area. The optical filter 1404 and the light diffusion unit 1405 can be arranged on the side from which illumination light is emitted. Further, a cover can be disposed on the outermost part of the illumination apparatus 1400 as necessary.

The illumination apparatus 1400 is, for example, an apparatus for illuminating a room. The illumination apparatus 1400 may emit white light, daylight white light, or any color ranging from blue to red. The illumination apparatus 1400 can include a dimmer circuit for adjusting the light.

The illumination apparatus 1400 can include the organic light emitting element according to the present exemplary embodiment and a power circuit connected to the organic light emitting element. The power circuit converts alternate current voltage into direct current voltage. White light has a color temperature of 4200 degrees Kelvin (K), and daylight white light has a color temperature of 5000 K. The illumination apparatus 1400 can include a color filter.

The illumination apparatus 1400 according to the present exemplary embodiment can include a heat dissipation unit. The heat dissipation unit dissipates heat generated in the apparatus to the outside, and a material, such as a metal with high specific heat or a liquid silicon, can be used for the heat dissipation unit.

FIG. 13B is a schematic diagram illustrating an automobile as an example of a moving body according to the present exemplary embodiment. The automobile includes tail lamps as one example of a lightning fixture. An automobile 1500 includes a tail lamp 1501, and the tail lamp can be configured to illuminate in response to a driver's braking operation.

The tail lamp 1501 can include the organic light emitting element according to the present exemplary embodiment. The tail lamp 1501 can include a protection member for protecting the organic light emitting element. While any material can be used as long as the material is transparent and has a certain degree of strength, a protection member made of, for example, and polycarbonate may be used. Furandicarboxylic acid derivatives, acrylonitrile derivatives, and the like can be mixed with polycarbonate.

The automobile 1500 can include a car body 1503 and a window 1502 mounted on the car body 1503. The window 1502 can be a transparent display unless the window 1502 is used for checking the front and the rear of the automobile 1500. The transparent display can include the organic light emitting element according to the present exemplary embodiment. In this case, a constituent member, such as an electrode, included in the organic light emitting element is made of a transparent material.

The moving body according to the present exemplary embodiment can be an ocean vessel, an aircraft, or a drone. The moving body can include a body and a lightning fixture mounted on the body. The lightning fixture may emit light to indicate a position of the body. The lightning fixture includes the organic light emitting element according to the present exemplary embodiment.

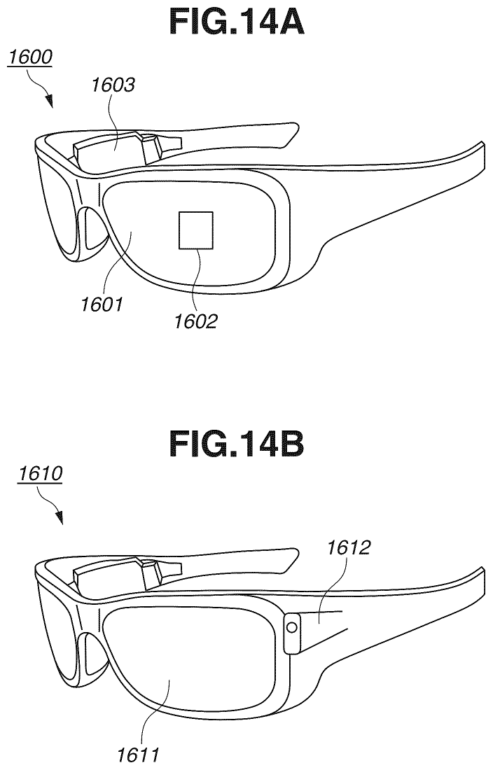

Application examples of the display apparatus according to the above-described exemplary embodiments will be described with reference to FIGS. 14A and 14B. The display apparatus can be applied to systems that can be worn as wearable devices, e.g., smart glasses, head-mounted displays (HMDs), and smart contact lenses. An image display apparatus used in the above-described application examples includes an image capturing apparatus capable of photoelectric conversion of visible light and a display apparatus capable of emitting visible light.

FIG. 14A illustrates a pair of glasses (smart glasses) 1600 according to an application example. An image capturing apparatus 1602, such as a complementary metal-oxide semiconductor (CMOS) sensor or a single-photon avalanche diode (SAPD), is disposed on the front of a lens 1601 of the glasses 1600. The display apparatus according to the above-described exemplary embodiments is disposed on the back of the lens 1601.

The glasses 1600 further include a control apparatus 1603. The control apparatus 1603 functions as a power source for supplying power to the image capturing apparatus 1602 and the display apparatus according to the above-described exemplary embodiments. The control apparatus 1603 controls the operation of the image capturing apparatus 1602 and the display apparatus. An optical system to focus light onto the image capturing apparatus 1602 is formed on the lens 1601.

FIG. 14B illustrates a pair of glasses (smart glasses) 1610 according to an application example. The glasses 1610 include a control apparatus 1612. The control apparatus 1612 includes an image capturing apparatus corresponding to the image capturing apparatus 1602 and a display apparatus. An optical system for projecting light emitted from the display apparatus within the control apparatus 1612 is formed on a lens 1611, so that images are projected on the lens 1611. The control apparatus 1612 functions as a power source for supplying power to the image capturing apparatus and the display apparatus, and also controls the operations of the image capturing apparatus and the display apparatus. The control apparatus 1612 can include an eye-tracking unit to detect a wearer's gaze. The eye-tracking may use infrared light. An infrared light emitting unit emits infrared light to the eyeball of the user who is gazing at a displayed image. An image capturing unit including a light receiving element detects the emitted infrared light reflected on the eyeball, so that a captured image of the eyeball can be acquired. A reduction unit for reducing light emitted from the infrared light emitting unit to a display unit in a plan view is disposed to prevent degradation of image quality.

The user's gaze to the displayed image is detected from the captured image of the eyeball acquired by the infrared light image capturing. Any known method can be applied for the gaze detection using captured images of eyeballs. As an example, a gaze detection method based on a Purkinje image from reflection of light emitted on a cornea can be used.

More specifically, gaze detection processing based on the pupil-corneal reflection method is performed. In the pupil-corneal reflection method, a gaze vector representing the orientation (a rotation angle) of the eyeball is calculated based on the pupil image and the Purkinje image included in the captured image of the eyeball to detect the user's gaze.

The display apparatus according to an exemplary embodiment of the present disclosure can include an image capturing apparatus including a light emitting element and control the image displayed on the display apparatus based on the user's gaze information received from the image capturing apparatus.

Specifically, the display apparatus determines a first display region where the user is gazing at and a second display region other than the first display region based on the gaze information. The first display region and the second display region can be determined by the control apparatus included in the display apparatus, or with information about the first display region and the second display region determined by an external control device can be received. In the display region of the display apparatus, a display resolution of the first display region can be controlled to be higher than that of the second display region. In other words, a resolution of the second display region can be lower than that of the first display region.

The display region has the first display region and the second display region other than the first display region. Based on the gaze information, a higher-priority region is determined from the first and the second display regions. The first display region and the second display region can be determined by the control apparatus included in the display apparatus, or information about the display regions determined by an external control device can be received. A resolution of the higher-priority region can be controlled to be higher than that of the region other than the higher-priority region. In other words, a resolution of the region with a relatively lower priority can be reduced.

An artificial intelligence (AI) program can be used in determining the first display region or the high-priority region. The AI program can be configured as a model that uses images of eyeballs and the actual gazing directions of the eyeballs in the images as training data to estimate a gaze angle and a distance to an object being looked at with the image(s) of an eyeball. The AI program can be included in the display apparatus, the image capturing apparatus, or an external device. In a case where the AI program is included in the external apparatus, the information is transmitted to the display apparatus through communication.

When display control is performed based on visual recognition detection, the display apparatus can be applied to a pair of smart glasses further including an image capturing apparatus for capturing images of the outside. The smart glasses can display information about a captured outside image in real time.

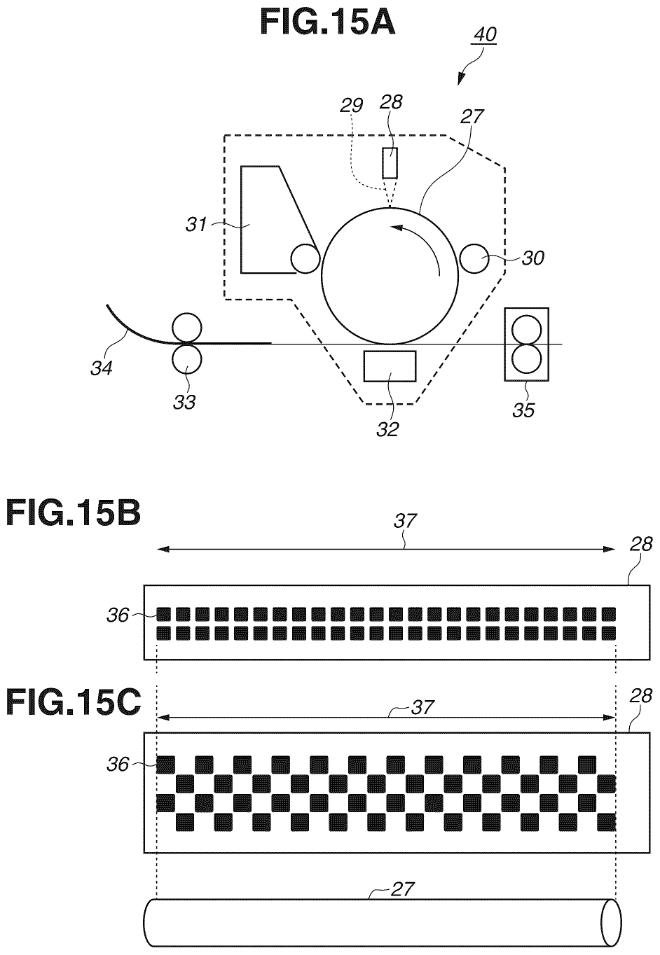

FIG. 15A illustrates the image forming apparatus according to an exemplary embodiment of the present disclosure. FIG. 15A is a schematic diagram illustrating an image forming apparatus 40 according to an exemplary embodiment of the present disclosure. The image forming apparatus 40 includes a photosensitive member 27, an exposure light source 28, a development unit 31, a charging unit 30, a transfer device 32, a conveyance roller 33, and a fixing unit 35.

Light 29 is emitted from the exposure light source 28 to form an electrostatic latent image on the surface of the photosensitive member 27. The exposure light source 28 includes the organic light emitting element according to the present exemplary embodiment. The development unit 31 contains toner and other components. The charging unit 30 electrically charges the photosensitive member 27. The transfer device 32 transfers a developed image to a recording medium 34. The conveyance roller 33 conveys the recording medium 34. For example, the recording medium 34 is a sheet of paper. The fixing unit 35 fixes an image formed on the recording medium 34.

FIGS. 15B and 15C are schematic diagrams each illustrating an arrangement of a plurality of light emitting units 36 on an elongated substrate in the exposure light source 28. Directions 37 are parallel to the axis of the photosensitive member 27. The directions 37 represent a row direction in which the organic light emitting elements are arranged. The row direction is same as the rotation axis direction of the photosensitive member 27. The directions 37 can be referred to as a long axis direction of the photosensitive member 27.

FIG. 15B illustrates an arrangement of the light emitting units 36 in the long axis direction of the photosensitive member 27. The form illustrated in FIG. 15C is different from that in FIG. 15B, and the light emitting units 36 are alternately arranged in the first and the second rows each in the column direction. The first row and the second row are arranged at different positions in the row direction.

In the first row, the light emitting units 36 are arranged at intervals. In the second row, the light emitting units 36 are arranged at positions corresponding to the intervals between the light emitting units 36 in the first row. In other words, the light emitting units 36 are also arranged at intervals in the column direction.

The arrangement illustrated in FIG. 15C can be described as being in a lattice pattern, a staggered pattern, or a checkerboard pattern.

As described above, using an apparatus including the organic light emitting element according to the present exemplary embodiment makes it possible to stably display an image with high quality for a long period of time.

According to the present disclosure, a light emitting apparatus with an efficient arrangement of the bypass capacitors can be provided. This makes it possible to supply stable power-source voltage to the light emitting apparatus and circuitry mounted on the light emitting apparatus.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims priority to and the benefit of Japanese Patent Application No. 2024-093959, filed Jun. 10, 2024, which is hereby incorporated by reference herein in its entirety.

What is claimed is:

1. A light emitting apparatus having a first side extending in a first direction, a second side opposite the first side extending in the first direction, and a third side extending in a second direction orthogonal to the first direction, to which a first power-supply voltage and a second power-supply voltage having a value different from a value of the first power-supply voltage are supplied, the light emitting apparatus comprising:
a light emitting region including a plurality of light emitting elements disposed along the first direction;
a plurality of driving circuits configured to drive corresponding light emitting elements among the plurality of light emitting elements;
a plurality of pads disposed along the first direction between the first side and the light emitting region, each of the pads configured to connect to an external terminal; and
a capacitor element to which the first power-source voltage and the second power-source voltage are supplied,
wherein the capacitor element is disposed between the second side and the light emitting region.

2. The light emitting apparatus according to claim 1, further comprising:
a current regulation circuit configured to regulate an amount of current output from the plurality of driving circuits; and
a plurality of the capacitor elements to which the first power-source voltage and the second power-source voltage are each supplied,
wherein the current regulation circuit is disposed between one capacitor of the plurality of capacitor elements and another capacitor element of the plurality of capacitor elements.

3. The light emitting apparatus according to claim 2, wherein the plurality of capacitor elements and the current regulation circuit are disposed along the first direction.

4. The light emitting apparatus according to claim 2, further comprising:
a plurality of the current regulation circuits,
wherein a first current regulation circuit of the plurality of current regulation circuits is disposed between a first capacitor element of the plurality of capacitor elements and a second capacitor element of the plurality of capacitor elements, and
wherein a second current regulation circuit of the plurality of current regulation circuits is disposed between a third capacitor element of the plurality of capacitor elements and a fourth capacitor element of the plurality of capacitor elements.

5. The light emitting apparatus according to claim 4, wherein the plurality of capacitor elements is disposed along the first direction.

6. The light emitting apparatus according to claim 4, wherein a fifth capacitor element to which the first power-source voltage and the second power-source voltage are supplied, is disposed between the first side and the light emitting region.

7. The light emitting apparatus according to claim 6, wherein the fifth capacitor and one pad of the plurality of pads are disposed along the first direction.

8. The light emitting apparatus according to claim 6, further comprising metallic wiring having a first portion disposed along the first side, a second portion disposed along the second side, and a third portion disposed along the third side in a plan view relative to the light emitting region,
wherein, in the plan view, the first portion includes a first region and a second region,
wherein the first region is formed within a first distance to the first side in the second direction,
wherein the second region is formed within a second distance to the first side in the second direction, the second distance longer than the first distance, and
wherein the fifth capacitor element is disposed between the first region and the light emitting region, between the second region and the third side.

9. The light emitting apparatus according to claim 8, wherein, a sixth capacitor element to which the first power-source voltage and the second power-source voltage are supplied, is disposed in a region between a fourth side opposed to the third side and the second region.

10. The light emitting apparatus according to claim 1, further comprising another capacitor element to which the first power-source voltage and the second power-source voltage are supplied, disposed between the first side and the light emitting region.

11. The light emitting apparatus according to claim 1, further comprising a protection element connected to one pad of the plurality of pads,
wherein the protection element is disposed between the first side and the light emitting region.

12. The light emitting apparatus according to claim 11, wherein the protection element and the one pad are disposed in the first direction.

13. The light emitting apparatus according to claim 1,
wherein the first power-source voltage is supplied to one pad of the plurality of pads, and
wherein the second power-source voltage is supplied to another pad of the plurality of pads.

14. The light emitting apparatus according to claim 1, wherein a control signal for controlling the plurality of driving circuits is input to one pad of the plurality of pads.

15. The light emitting apparatus according to claim 1, wherein the capacitor element is a metal-insulator-semiconductor (MIS) capacitor.

16. The light emitting apparatus according to claim 1,
wherein the capacitor element is a metal-insulator-metal (MIM) capacitor, and
wherein a first metallic electrode and a second metallic electrode for forming the MIM capacitor are formed in the same wiring layer as each other, and an insulation member is disposed between the first metallic electrode and the second metallic electrode.

17. The light emitting apparatus according to claim 1, wherein the capacitor element is a metal-insulator-metal (MIM) capacitor, and wherein a first metallic electrode and a second metallic electrode for forming the MIM capacitor are formed in different wiring layers from each other, and an insulation member is disposed between the first metallic electrode and the second metallic electrode.

18. A light emitting module on which a plurality of the light emitting apparatuses according to claim 1 is disposed.

19. The light emitting module according to claim 18, further comprising:
a lens array configured to concentrate light output from the plurality of light emitting apparatuses.

20. An electronic device comprising:
a display unit including the light emitting apparatus according to claim 1;
a housing in which the light emitting apparatus is mounted; and
a communication unit mounted in the housing configured to communicate with an external device.
